(19) United States
(12) Patent Application Publication
(10) Pub. No.: US 2015/0003629 A1
(43) Pub. Date: Jan. 1, 2015

(54) PORTABLE WIRELESS SPEAKER SYSTEM

(71) Applicant: Jambanz LLC, Atlanta, GA (US)

(72) Inventors: Lee Killian, Atlanta, GA (US); Robert McNae, Wayzata, MN (US); John Barousse, II, Metairie, LA (US); Ari Low, Wayzata, MN (US)

(21) Appl. No.: 14/487,473

(22) Filed: Sep. 16, 2014

Related U.S. Application Data
(60) Provisional application No. 61/901,224, filed on Nov. 7, 2013.

(51) Int. Cl. H04R 3/00; H03G 3/02

(52) U.S. Cl. CPC H04R 3/00; H03G 3/02; H04R 2420/07
USPC 381/77

(57) ABSTRACT

A portable wireless speaker system including a flexible spring band and a wireless speaker portion. The audio communication module is operably connected to the speaker module. The enclosure at least partially covers the speaker module and the audio communication module. The flexible spring band is capable of being positioned in an elongated configuration and a coiled configuration. The wireless speaker portion is attachable to the flexible spring band. The wireless speaker portion includes a speaker module, an audio communication module and an enclosure. The speaker module is capable of emitting sound. The audio communication module is capable of wirelessly receiving audio signals.

### REFERENCE TO RELATED APPLICATION

This application claims priority to U.S. Application No. 61/901,224, which was filed on Nov. 7, 2013, the contents of which are hereby incorporated by reference.

### FIELD OF THE INVENTION

The invention relates generally to components for an audio system. More particularly, the invention relates to a portable wireless speaker system that is removably attached to a user's body.

### BACKGROUND OF THE INVENTION

It is popular for persons to carry portable devices that are capable of playing music and/or videos. In certain situations, headphones are directly plugged into the portable device to listen to sound associated with the music and/or videos.

Other devices have been developed that enable wireless communication between the portable device and the speakers. An example of one such wireless communication protocol is Bluetooth. An advantage of using a standardized wireless communication protocol such as Bluetooth is that it enables a variety of portable devices to be connected to a variety of speakers. For example, wireless headphones have been developed that are positioned proximate a person's ear(s).

### SUMMARY OF THE INVENTION

An embodiment of the invention is directed to a portable wireless speaker system that includes a releasable mounting portion and a wireless speaker portion. The releasable mounting portion includes a flexible spring band that is positionable in an elongated configuration and a coiled configuration.

The wireless speaker portion includes a speaker module, an audio communication module and an enclosure. The speaker module is capable of emitting sound. The audio communication module is capable of wirelessly receiving audio information. The audio communication module is operably connected to the speaker module. The enclosure at least partially covers the speaker module and the audio communication module. The wireless speaker portion is attached to the flexible spring band.

Another embodiment of the invention is directed to a method of using a portable wireless speaker system. A wireless speaker portion is provided that includes a speaker module, an audio communication module and an enclosure. The audio communication module is operably connected to a speaker module. The enclosure at least partially covers the speaker module and the audio communication module.

The wireless speaker portion is attached to a flexible spring band. The flexible spring band is positioned in an elongated configuration. The flexible spring band is positioned adjacent to a portion of a person's body. The flexible spring band is moved to a coiled configuration where at least a portion of the flexible spring band extends around the portion of the person's body to retain the wireless speaker portion in a substantially stationary position with respect to the portion of the person's body. Audio signals are received with the audio communication module. Sound is emitted from the speaker module in the wireless speaker portion.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 is a first perspective view of the portable wireless speaker system according to an embodiment of the invention.

FIG. 2 is a second perspective view of the portable wireless speaker system.

FIG. 3 is an upper perspective view of a wireless speaker portion for use in the portable wireless speaker system.

FIG. 4 is a lower perspective view of the wireless speaker portion of FIG. 3.

FIG. 5 is a first side view of the wireless speaker portion.

FIG. 6 is a second side view of the wireless speaker portion.

FIG. 7 is a sectional view of the wireless speaker portion.

FIG. 8 is a sectional view of the portable wireless speaker system.

### DETAILED DESCRIPTION OF THE INVENTION

An embodiment of the invention is directed to a portable wireless speaker system, as illustrated and described herein. In certain embodiments, the portable wireless speaker system 10 includes a wireless speaker portion 12 and a releasable mounting portion 14.

The portable wireless speaker system 10 may be removably attached to a portion of a person's body such as a wrist. The portable wireless speaker system 10 thereby enables a person to listen to audio transmitted from a portable device as the person moves without the person having to carry speakers. The invention also enables the person to listen to audio without cords extending between the speakers and the device on which the audio is saved or on which an audio signal is received.

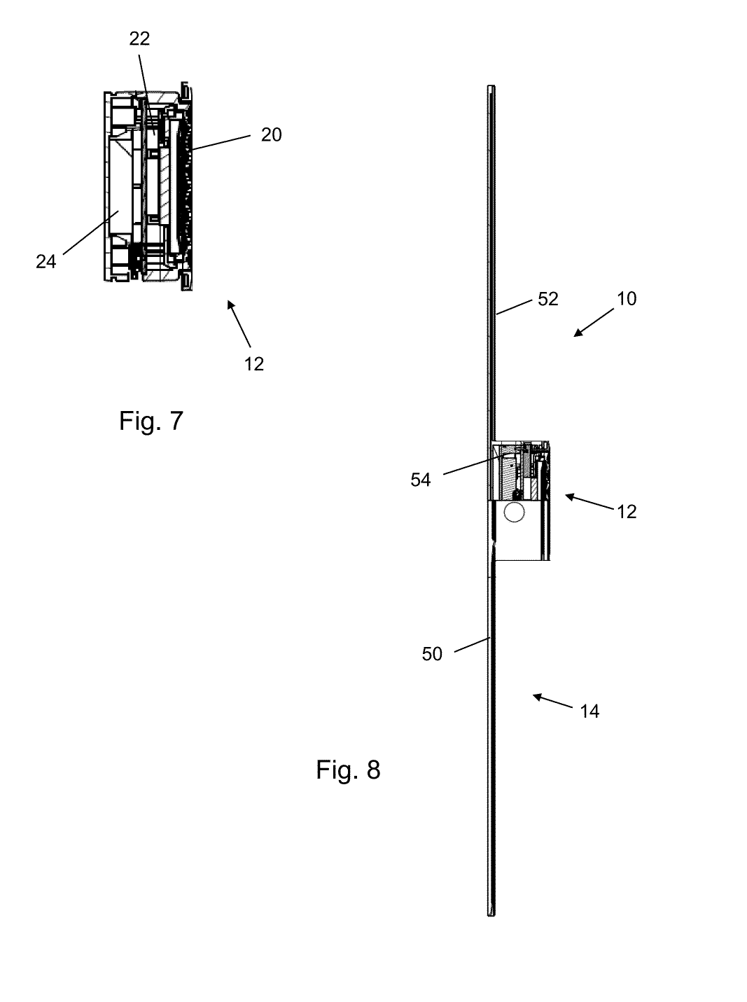

The wireless speaker portion 12 comprises a speaker module 20, an audio communication module 22 and a power module 24, as illustrated in FIG. 7. The speaker module 20 may be any of a variety of components that are able to emit sound such as a conventional speaker.

The audio communication module 22 is capable of receiving audio transmissions. The audio transmissions can be transmitted from a variety of devices using a variety of protocols. In certain embodiments, the audio can be transmitted according to the provisions of one of the Bluetooth standards. In certain embodiments, audio files are stored on the device that emits the audio transmissions. In other embodiments, the device receives audio transmissions such as radio.

The power module 24 may include at least one battery. In certain embodiments, the power module 24 may be removably mounted in the wireless speaker portion 12 such that the power module 24 can be replaced when depleted.

In other embodiments, the power module 24 may be rechargeable. To facilitate recharging of the power module 24, a connection port 26 may be provided on a surface of the wireless speaker portion 12. The connection port 26 may assume a variety of configurations. In certain embodiments, the connection port 26 may be a micro or mini universal serial bus (USB) connector.

In addition to facilitating recharging the power module 24, it is also possible for the connection port 26 to be used in programming the components in the wireless speaker module 12 such as updating software stored therein.

The wireless speaker portion 12 may also include a power control 30. When the power control 30 is in first position, the wireless speaker portion 12 is turned on. When the power control 30 is in a second position, the wireless speaker portion 12 is turned off. The power control 30 may include an identifier to indicate the function of the power control 30.

The wireless speaker portion 12 may also have at least one volume control 32. In certain embodiments, there are two volume control buttons. Pressing the first volume control causes the volume of sound emitted by the speaker module 20 to be increased. Pressing the second volume control causes the volume of sound emitted by the speaker module 20 to be decreased. The at least one volume control 32 may include an identifier to indicate the function of each of volume controls.

While it is illustrated that the at least one volume control 32 is separate from the power control 30, it is also possible for the at least one volume control 32 to be combined with the power control 30.

At least one of the power control 30 and the volume control 32 may be used in conjunction with additional features. For example, pressing the power control 30 for less than one second may cause the wireless speaker portion 12 to turn on or off and pressing the power control 30 for more than one second may cause the wireless speaker portion 12 to enter a programming mode such as for pairing the wireless speaker portion 12 with a particular device that is desired to transmit audio to the wireless speaker portion 12.

In yet another embodiment, the audio communication module 22 may be a wireless communication module that is capable of two-way communication. In such a configuration, the wireless speaker module 12 may also include a microphone.

The components of the wireless speaker portion 12 may be mounted within an enclosure 40 that protects the components of the wireless speaker portion 12 such as from damage. Alternatively or additionally, the enclosure 40 may protect the components of the wireless speaker portion 12 from water.

The shape of the enclosure 40 may be selected to provide the wireless speaker portion 12 with a desired appearance. In certain embodiments, the enclosure 40 may have a generally round configuration.

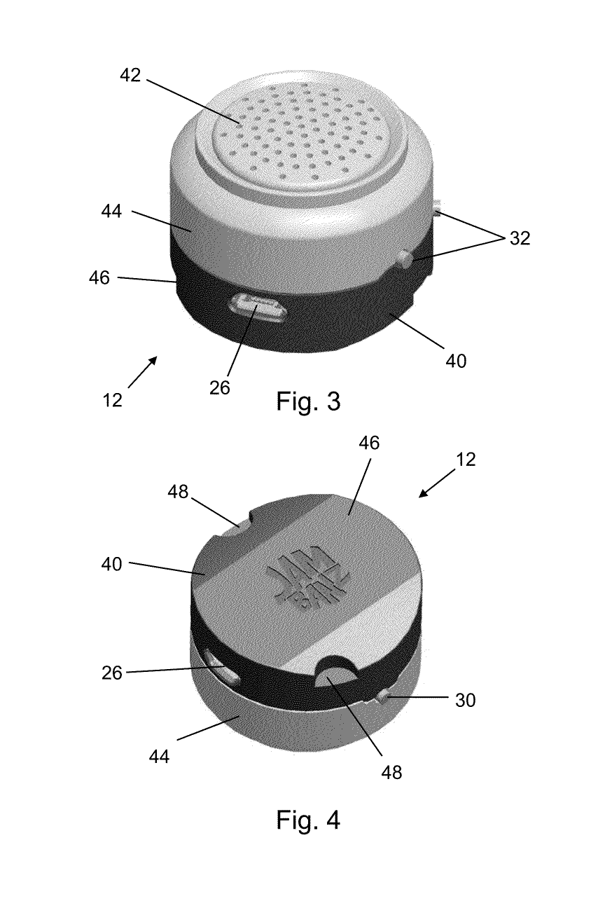

An upper surface of the enclosure 40 may have a plurality of apertures 42 formed therein. The apertures 42 may enhance the ability of sound to be emitted from the speaker module 20. The apertures 42 may be arranged in a pattern. In certain embodiments, the apertures 42 may be arranged in a plurality of circles as illustrated in FIG. 3.

The enclosure 42 may be fabricated in multiple components. In certain embodiments, the enclosure includes an upper enclosure section 44 and a lower enclosure section 46. The upper enclosure section 44 and the lower enclosure section 46 may be attached together using a variety of mechanisms such as adhesives and screws. The attachment mechanisms may enable the upper enclosure section 44 to be separated from the lower enclosure section 46 such as to replace the batteries.

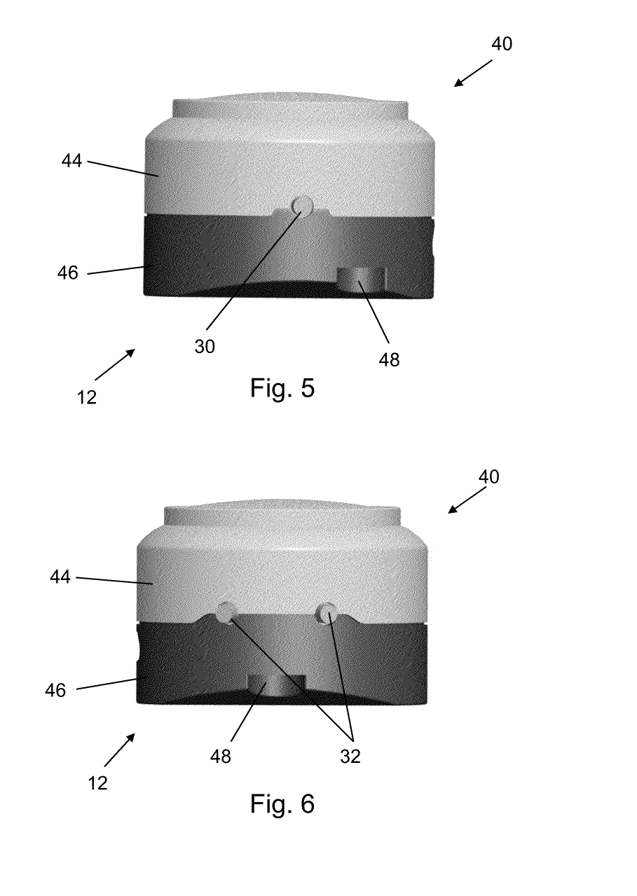

The buttons used to control the operation of the wireless speaker portion 12 may extend therefrom proximate the intersection of the upper enclosure section 44 and the lower enclosure section 46, as illustrated in FIGS. 3-6.

At least a portion of the lower surface of the enclosure 40 may be shaped to conform to a portion of the person's body on which the portable wireless speaker system 10 is intended to be worn. Alternatively, at least a portion of the lower surface of the enclosure 40 may be curved upwardly as illustrated in FIG. 4.

The wireless speaker portion 12 may include an alignment mechanism 46 that facilitates accurate placement of the wireless speaker portion 12 in the releasable mounting portion 14 so that the buttons on the wireless speaker portion 12 such as the power control 30 can be accurately identified and operated when the wireless speaker portion 12 is mounted in the releasable mounting portion 14.

In one embodiment, the alignment mechanism 48 includes a recess formed in a lower surface of the wireless speaker portion 12. The recess should have a shape and size that facilitates the user readily identifying a correct orientation of the wireless speaker portion 12 with respect to the releasable mounting portion 14.

In certain embodiments, the alignment mechanism 48 comprises multiple recesses. While it is illustrated that the recesses have a similar configuration, it is possible to form the recesses with different configurations to thereby enable a user to determine the correct orientation of the wireless speaker portion 12 in the releasable mounting portion 14. For example, the recesses may be formed with different shapes and/or sizes. The differences between the shape and/or size should be sufficiently great such that a person can readily determine such difference.

The recesses may be oriented at an angle with respect to each other. For example, one of the recesses may be oriented at a 12:00 position and another recess may be oriented at a 7:00 position, as illustrated in FIG. 4.

The releasable mounting portion 14 may be configured for removable attachment to a portion of a wearer's body. For example, the releasable mounting portion 14 may have an elongated configuration that is capable of extending at least partially around the wearer's body such as a wearer's wrist.

In certain embodiments, the releasable mounting portion 14 or bracelet is similar to a slap bracelet that includes at least one flexible spring band 50. In other embodiments, there are a plurality of the flexible spring bands 50. The flexible spring bands 50 may be fabricated from a variety of materials. An example of one such material is flexible stainless steel.

In certain embodiments, the flexible spring band 50 is a bi-stable ribbon spring, which has unique characteristics in that the spring has a first stable generally linear state and a second stable coiled state. When flexed the releasable mounting portion 14 self-coils around a user's wrist assuming the stable coiled state. The releasable mounting portion 14 can be removed by straightening to the stable generally linear state.

The at least one flexible spring band 50 may at least partially be covered, as illustrated in FIG. 8. In certain embodiments, the at least one flexible spring band 50 is entirely covered with the cover material 52. The cover material 52 may be a flexible and/or resilient plastic.

The releasable mounting portion 14 also includes a recess 54 formed therein that is adapted to receive at least a portion of the wireless speaker portion 12. In certain embodiments, the recess 54 receives substantially all of the wireless speaker portion 12. The area of the wireless speaker portion 12 from which the sound is emitted is not covered by the releasable mounting portion 14.

In certain embodiments, the part of the releasable mounting portion 14 that extends over the wireless speaker portion 12 may be fabricated from a flexible and/or resilient material so that the releasable mounting portion 14 can expand during the process of putting the wireless speaker portion 12 into and out of engagement with the releasable mounting portion 14.

Forming the releasable mounting portion 14 from a flexible and/or resilient material also enables the buttons on the wireless speaker portion 12 to be accessed without apertures being formed in the releasable mounting portion 14 through which the buttons are accessed.

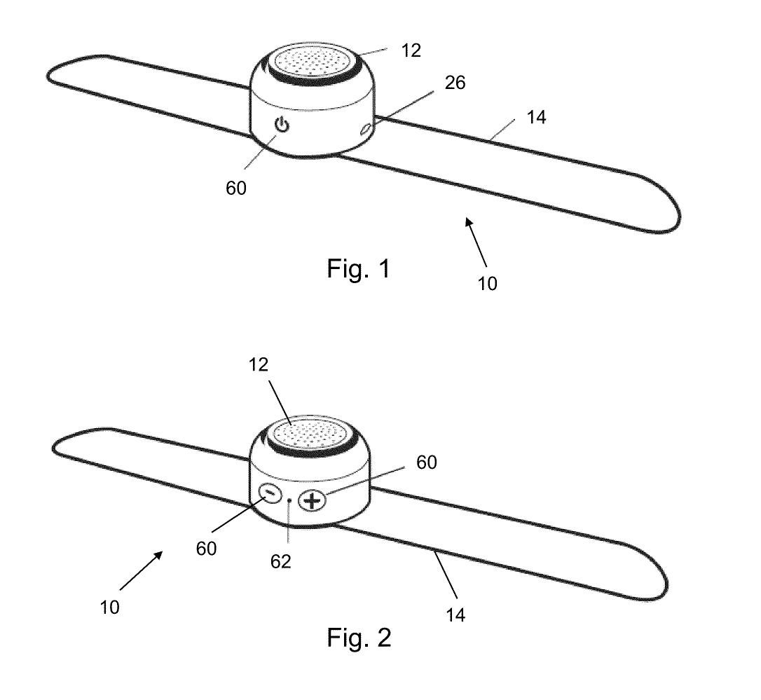

The releasable mounting portion 14 may include an area 60 having a different height than the other portions to enhance the ability of the user to identify the locations of the buttons, as illustrated in FIGS. 1 and 2. In certain embodiments, the different height area 60 is elevated or recessed. Proximate thereto, identifying indicia such as graphics or text may be provided to assist the user in identifying the function of the associated button.

The wireless speaker portion 12 may be formed in a color that is similar to a color of the releasable mounting portion 14. Alternatively, the wireless speaker portion 12 may be formed from a color that complements or contrasts from the color from which the releasable mounting portion 14 is formed.

Because of the configuration of the portable wireless speaker system 10, it is possible for a person to purchase one wireless speaker portion 12 and multiple releasable mounting portions 14 so that different releasable mounting portions 14 may be used depending on the clothing or accessories worn by the person who intends to wear the portable wireless speaker system 10.

In the preceding detailed description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The preceding detailed description, therefore, is not to be taken in a limiting sense, and the scope of the present invention is defined by the appended claims.

It is contemplated that features disclosed in this application, as well as those described in the above applications incorporated by reference, can be mixed and matched to suit particular circumstances. Various other modifications and changes will be apparent to those of ordinary skill.

1. A portable wireless speaker system comprising:
a flexible spring band that is positionable in an elongated configuration and a coiled configuration; and
a wireless speaker portion that is attachable to the flexible spring band, wherein the wireless speaker portion comprises:
a speaker module that is capable of emitting sound;
an audio communication module that is capable of wirelessly receiving audio signals, wherein the audio communication module is operably connected to the speaker module; and
an enclosure that at least partially covers the speaker module and the audio communication module.

2. The portable wireless speaker system of claim 1, wherein the wireless speaker portion further comprises:
a power control operably attached to the audio communication module; and
a volume control operably attached to the speaker module.

3. The portable wireless speaker system of claim 1, wherein the wireless speaker portion further comprises:
a battery that is operably attached to at least one of the speaker module and the audio communication module; and
a connection port operably attached to the battery for charging the power module.

4. The portable wireless speaker system of claim 1, and further comprising a cover material that extends over at least a portion of the flexible spring band, wherein the cover material has a recess formed therein and wherein at least a portion of the enclosure is positionable in the cover material recess.

5. The portable wireless speaker system of claim 4, wherein the cover material substantially covers the flexible spring band.

6. The portable wireless speaker system of claim 4, wherein the cover material is at least partially fabricated from a resilient material.

7. The portable wireless speaker system of claim 4, wherein the enclosure comprises at least one first alignment mechanism, wherein the cover material comprises at least one second alignment mechanism and wherein the at least one first alignment mechanism engages the at least one second alignment mechanism when the wireless speaker portion is in a specified position with respect to the cover material.

8. The portable wireless speaker system of claim 7, wherein there are two first alignment mechanisms and wherein there are two second alignment mechanisms.

9. The portable wireless speaker system of claim 1, wherein the wireless speaker portion further comprises a microphone operably attached to the audio communication module.

10. The portable wireless speaker system of claim 1, wherein the flexible spring band comprises a bi-stable ribbon spring.

11. A method of using a portable wireless speaker system comprising:
providing a wireless speaker portion that comprises a speaker module, an audio communication module and an enclosure, wherein the audio communication module is operably connected to a speaker module and wherein the enclosure at least partially covers the speaker module and the audio communication module;
attaching the wireless speaker portion to a flexible spring band;
positioning the flexible spring band in an elongated configuration;
positioning the flexible spring band adjacent to a portion of a person's body;
moving the flexible spring band to a coiled configuration where at least a portion of the flexible spring band extends around the portion of the person's body to retain the wireless speaker portion in a substantially stationary position with respect to the portion of the person's body;
receiving audio signals with the audio communication module; and
emitting sound from the speaker module.

12. The method of claim 11, and further comprising:
controlling operation of the wireless speaker portion with a power control that is operably attached to the audio communication module; and
controlling a volume of sound emitted by the speaker module with a volume control that is operably attached to the speaker module.

13. The method of claim 11, and further comprising:
providing power to at least one of the speaker module and the audio communication module with a battery; and
charging the battery using a connection port that is operably attached to the power module.

14. The method of claim 11, and further comprising covering at least a portion of the flexible spring band with a cover material, wherein the cover material has a recess formed therein.

15. The method of claim 14, and further comprising substantially covering the flexible spring band with the cover material.

16. The method of claim 14, and further comprising at least partially fabricating the cover material from a resilient material.

17. The method of claim 14, and further comprising:
providing at least one first alignment mechanism on the enclosure;
providing at least one second alignment mechanism on the cover material; and
engaging the at least one first alignment mechanism and the at least one second alignment mechanism when the wireless speaker portion is in a specified position with respect to the cover material.

18. The method of claim 11, wherein the wireless speaker portion further comprises a microphone operably attached to the audio communication module.
